(19) United States
(12) Patent Application Publication
(10) Pub. No.: US 2026/0271580 A1
(43) Pub. Date: Sep. 10, 2026

(54) DISPLAY DEVICE

(71) Applicant: Sharp Display Technology Corporation, Kameyama City, Mie (JP)

(72) Inventor: Tadayoshi MIYAMOTO

(21) Appl. No.: 19/125,498

(22) PCT Filed: Nov. 8, 2022
(86) PCT No.: PCT/JP2022/041573

§ 371 Date: Apr. 29, 2025

(51) Int. Cl. H10K 59/80

(52) U.S. Cl. CPC H10K 59/80515; H10K 59/873

(57) ABSTRACT

A light-emitting-element layer includes: a plurality of first electrodes; a plurality of third electrodes; a first edge cover provided in common; a plurality of fourth electrodes; a plurality of light-emitting functional layers; and a second electrode provided in common, all of which are sequentially stacked on top of another in association with a plurality of subpixels that constitute a display region. Each of the third electrodes exposed from the first edge cover is provided with a plurality of opening portions penetrating through the third electrode. The third electrodes exposed from the first edge cover are covered with the respective fourth electrodes, and each of the fourth electrodes has a surface provided with a plurality of recess portions in association with the plurality of opening portions.

### TECHNICAL FIELD

The present invention relates to a display device.

### BACKGROUND ART

In recent years, light-emitting organic electroluminescence (EL) display devices using organic EL elements have attracted attention as a replacement for liquid crystal display devices. An organic EL display device includes, for example: a base substrate; a thin-film transistor (TFT) layer provided on the base substrate; an organic-EL-element layer provided on the TFT layer; and a sealing film provided on the organic EL element layer. Here, an organic EL element includes: a first electrode provided on the TFT layer; an organic EL layer provided on the first electrode and serving as a light-emitting functional layer; and a second electrode provided on the organic EL layer.

For example, Patent Document 1 describes that a protruding portion is formed on a surface of the first electrode because of a protrusion on a surface of a passivation film. The protruding portion reflects light generated from a light-emitting-element layer and enhances light emission efficiency.

### CITATION LIST

### Patent Literature

[Patent Document 1] United States Patent Application Publication No. 2017/0125740

### SUMMARY OF INVENTION

### Technical Problems

Suppose a case where, in the organic EL display device, an organic EL layer is formed on the first electrode, for example, by ink-jet printing or with a solution applying apparatus such as various coaters. When a coating film to form the organic EL layer is dried, a solute component of the coating film is likely to be deposited on an edge of the coating film by the coffee ring effect. Inevitably, the organic EL layer is relatively thin on a center portion of the first electrode and relatively thick on an edge portion of the first electrode. In this case, the variations in film thickness of the organic EL layer in a subpixel cause unevenness in emission of the light and the resulting decrease in light emission efficiency. Such an organic EL display device has room for improvement.

The present invention is conceived in view of the above problems, and sets out to reduce variations in thickness of a light-emitting functional layer in a subpixel.

### Solution to Problems

In order to achieve the above object, a display device according to the present invention includes: a base substrate; a thin-film transistor layer provided on the base substrate; and a light-emitting-element layer provided on the thin-film transistor layer, and including a plurality of first electrodes, a first edge cover provided in common, a plurality of light-emitting functional layers, and a second electrode provided in common, all of which are sequentially stacked on top of another in association with a plurality of subpixels that constitute a display region. Between the plurality of first electrodes and the first edge cover, a plurality of third electrodes is provided in association with the plurality of subpixels. Each of the third electrodes exposed from the first edge cover is provided with a plurality of opening portions penetrating through the third electrode. Between the first edge cover and the plurality of light-emitting functional layers, a plurality of fourth electrodes is provided in association with the plurality of subpixels to cover the plurality of third electrodes exposed from the first edge cover. Each of the fourth electrodes has a surface provided with a plurality of recess portions in association with the plurality of opening portions.

### Advantageous Effect of Invention

The present invention can reduce variations in thickness of a light-emitting functional layer in a subpixel.

### BRIEF DESCRIPTION OF DRAWINGS

FIG. 1 is a plan view of a schematic configuration of an organic EL display device according to a first embodiment of the present invention.

FIG. 2 is a plan view of a display region of the organic EL display device according to the first embodiment of the present invention.

FIG. 3 is a cross-sectional view of the display region of the organic EL display device according to the first embodiment of the present invention.

FIG. 4 is an equivalent circuit diagram of a TFT layer included in the organic EL display device according to the first embodiment of the present invention.

FIG. 5 is a cross-sectional view of an organic EL layer included in the organic EL display device according to the first embodiment of the present invention.

FIG. 6 illustrates schematic views showing a principle of forming a third electrode included in the organic EL display device according to the first embodiment of the present invention.

### DESCRIPTION OF EMBODIMENTS

Embodiments of the present invention will be described in detail below with reference to the drawings. Note that the present invention shall not be limited to the embodiments below.

### First Embodiment

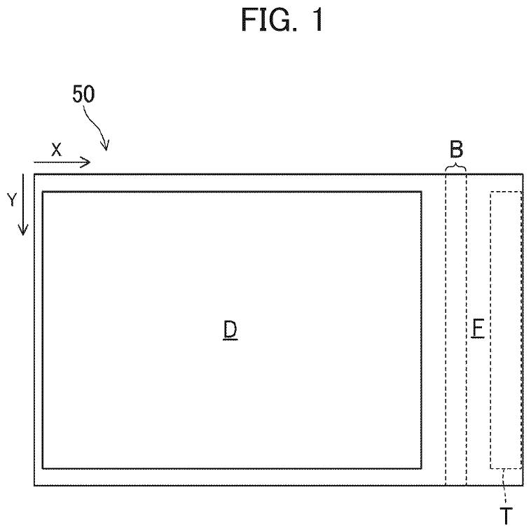

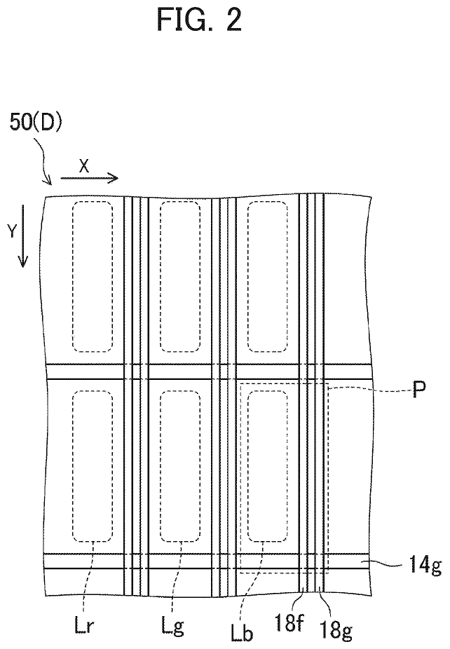

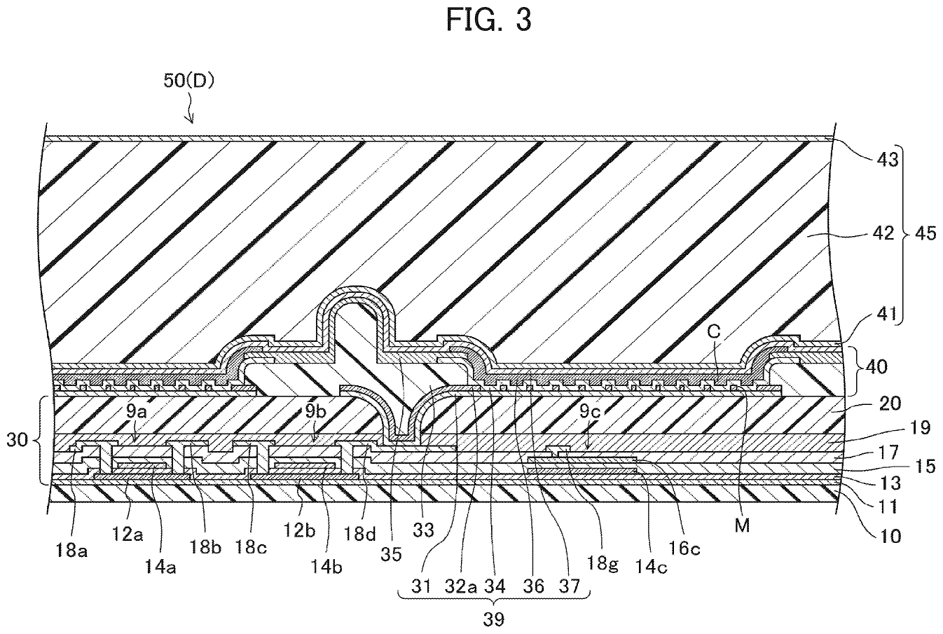

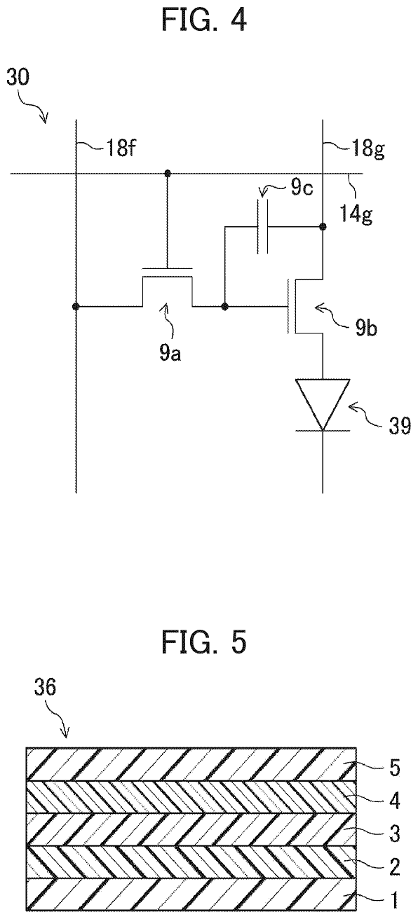

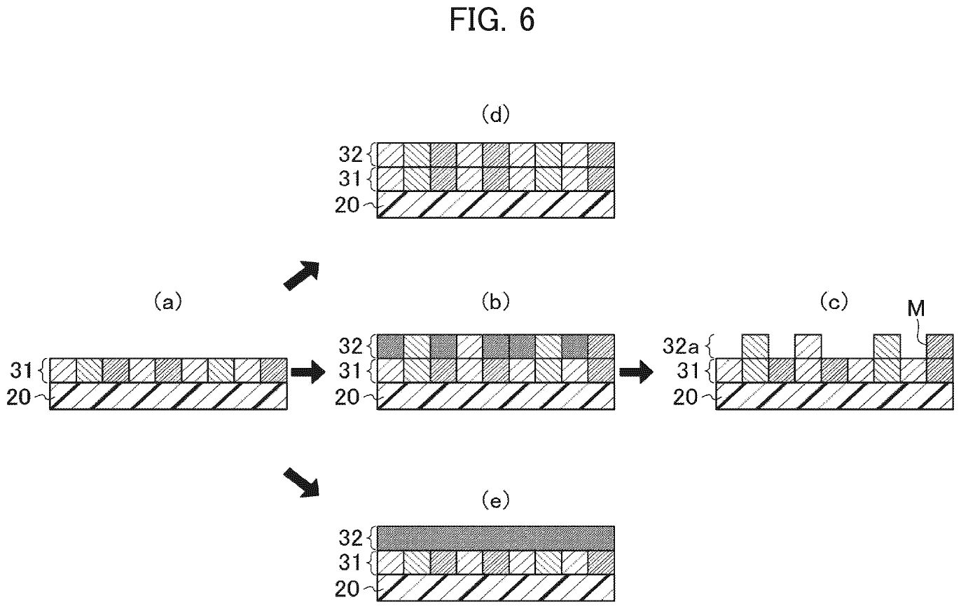

FIGS. 1 to 6 illustrate a first embodiment of a display device according to the present invention. Note that, in the embodiments below, an organic EL display device including an organic-EL-element layer is exemplified as a display device including a light-emitting-element layer. Here, FIG. 1 is a plan view of a schematic configuration of an organic EL display device 50 according to this embodiment. FIG. 2 and FIG. 3 are respectively a plan view and a cross-sectional view of a display region D of the organic EL display device 50. FIG. 4 is an equivalent circuit diagram of the TFT layer 30 included in the organic EL display device 50. FIG. 5 is a cross-sectional view of the organic EL layer 36 included in the organic EL display device 50. FIG. 6 illustrates schematic views showing a principle of forming a third electrode 32a included in the organic EL display device 50.

As illustrated in FIG. 1, the organic EL display device 50 includes, for example: the display region D shaped into a rectangle and displaying an image; and a picture-frame region F shaped into a picture-frame shape and provided around the display region D. Note that this embodiment exemplifies the display region D shaped into a rectangle. Examples of the rectangle include such substantial rectangles as a rectangle having arc-like sides, a rectangle having rounded corners, and a rectangle having partially notched sides.

The display region D illustrated in FIG. 2 includes a plurality of subpixels P arranged in a matrix. Moreover, in the display region D, as illustrated in FIG. 2, for example, subpixels P having red light-emitting regions Lr for presenting red, subpixels P having green light-emitting regions Lg for presenting green, and subpixels P having blue light-emitting regions Lb for presenting blue are provided side by side. Note that, in the display region D, for example, neighboring three subpixels P each having one of a red light-emitting region Lr, a green light-emitting region Lg, and a blue light-emitting region Lb constitute one pixel.

The picture-frame region F in FIG. 1 has a right end portion provided with a terminal unit T extending in one direction (in a Y-direction in the drawing). Moreover, as illustrated in FIG. 1, the picture-frame region F includes, for example, a folding portion B between the display region D and the terminal unit T. The folding portion B, provided to the terminal unit T toward the display region D and extending in one direction (in the Y-direction in the drawing), is foldable around a folding axis in the Y-direction in the drawing at an angle of 180° (foldable in a U-shape).

As illustrated in FIG. 3, the organic EL display device 50 includes: a resin substrate 10 provided as a base substrate; a TFT layer 30 provided on the resin substrate 10; an organic-EL-element layer 40 provided on the TFT layer 30 to serve as a light-emitting-element layer; and a sealing film 45 provided on the organic-EL-element layer 40.

The resin substrate 10 is made of, for example, such a material as polyimide resin.

The TFT layer 30 in FIG. 3 includes: a base coat film 11 provided on the resin substrate layer 10; a plurality of first TFTs 9a, a plurality of second TFTs 9b, and a plurality of capacitors 9c, all of which are provided on the base coat film 11; and a protective insulating film 19 and a planarization film 20 sequentially provided above the first TFTs 9a, the second TFTs 9b, and the capacitors 9c. Here, the TFT layer 30 includes, as illustrated in FIG. 2, a plurality of gate lines 14g extending in parallel with one another in an X-direction in the drawing. Furthermore, the TFT layer 30 includes, as illustrated in FIG. 2, a plurality of source lines 18f extending in a direction intersecting with (perpendicular to) the plurality of gate lines 14g; that is, extending in parallel with one another in the Y-direction in the drawing. Moreover, the TFT layer 30 includes, as illustrated in FIG. 2, a plurality of power supply lines 18g extending in parallel with one another in the Y-direction in the drawing. Thus, as illustrated in FIG. 2, the power supply lines 18g and the source lines 18f are provided side by side. Moreover, in the TFT layer 30, as illustrated in FIG. 4, each subpixel P includes: a first TFT 9a; a second TFT 9b; and a capacitor 9c. Note that the TFT layer 30 illustrated in FIG. 3 includes: the base coat film 11; a semiconductor film serving as, for example, a semiconductor layer 12a to be described later; a gate insulating film 13; a first metal film serving as, for example, a gate line 14g; a first interlayer insulating film 15; a second metal film serving as, for example, an upper conductive layer 16c to be described later; a second interlayer insulating film 17; a third metal film serving as, for example, a source line 18f and a power supply line 18g; the protective insulating film 19; and the planarization film 20, all of which are sequentially stacked on top of another above the resin substrate 10.

Each of the base coat film 11, the gate insulating film 13, the first interlayer insulating film 15, the second interlayer insulating film 17, and the protective insulating film 19 is an inorganic monolayer insulating film made of such a substance as, for example, silicon nitride, silicon oxide, or silicon oxynitride. Alternatively, each film is an inorganic multilayer insulating film made of these substances.

As illustrated in FIG. 4, in each subpixel P, the first TFT 9a is electrically connected to the corresponding gate line 14g and source line 18f. Here, as illustrated in FIG. 3, the first TFT 9a includes: the semiconductor layer 12a provided on the base coat film 11; a gate electrode 14a provided above the semiconductor layer 12a through the gate insulating film 13; and a source electrode 18a and a drain electrode 18d provided on the second interlayer insulating film 17 and spaced apart from each other.

The semiconductor layer 12a is a semiconductor film made of, for example, polysilicon such as low-temperature polysilicon (LTPS). The second semiconductor layer 12a includes: a source region and a drain region defined to be spaced apart from each other; and a channel region defined between the source region and the drain region.

The gate electrode 14a is provided to overlap with the channel region of the semiconductor layer 12a. The gate electrode 14a controls conduction between the source region and the drain region of the semiconductor layer 12a. Here, similar to the gate line 14g, the gate electrode 14a is formed of the first metal film.

The source electrode 18a and the drain electrode 18b illustrated in FIG. 3 are electrically connected to the source region and the drain region of the semiconductor layer 12a through respective contact holes formed in the gate insulating film 13, the first interlayer insulating film 15, and the second interlayer insulating film 17. Here, similar to the source line 18f and the power supply line 18g, the source electrode 18a and the drain electrode 18b are formed of the third metal film.

As illustrated in FIG. 4, in each subpixel P, the second TFT 9b is electrically connected to the corresponding first TFT 9a and power supply line 18g. Here, as illustrated in FIG. 3, the second TFT 9b includes: a semiconductor layer 12b provided on the base coat film 11; a gate electrode 14b provided above the semiconductor layer 12b through the gate insulating film 13; and a source electrode 18c and a drain electrode 18d provided on the second interlayer insulating film 17 and spaced apart from each other.

Similar to the semiconductor layer 12a, the semiconductor layer 12b is a semiconductor film formed of, for example, polysilicon such as LTPS. The second semiconductor layer 12b includes: a source region and a drain region defined to be spaced apart from each other; and a channel region defined between the source region and the drain region.

The gate electrode 14b is provided to overlap with the channel region of the semiconductor layer 12b. The gate electrode 14b controls conduction between the source region and the drain region of the semiconductor layer 12b. Here, similar to the gate line 14g, the gate electrode 14b is formed of the first metal film.

The source electrode 18c and the drain electrode 18d illustrated in FIG. 3 are electrically connected to the source region and the drain region of the semiconductor layer 12b through respective contact holes formed in a multilayer film including the gate insulating film 13, the first interlayer insulating film 15, and the second interlayer insulating film 17. Here, similar to the source line 18f and the power supply line 18g, the source electrode 18c and the drain electrode 18d are formed of the third metal film.

Note that this embodiment exemplifies that the semiconductor layers 12a and 12b are formed of semiconductor films made of polysilicon. Alternatively, the semiconductor layers 12a and 12b may be formed of semiconductor films made of, for example, an oxide semiconductor such as an In—Ga—Zn—O-based oxide semiconductor. Furthermore, the TFT layer 30 may have a hybrid structure provided with each of: a TFT having a semiconductor layer formed of polysilicon; and a TFT having a semiconductor layer formed of an oxide semiconductor.

As illustrated in FIG. 4, in each subpixel P, the capacitor 9c is electrically connected to the corresponding first TFT 9a and power supply line 18g. Here, as illustrated in FIG. 3, the capacitor 9c includes: a lower conductive layer 14c formed of the first metal film; an upper conductive layer 16c formed of the second metal film; and the first interlayer insulating film 15 provided between the lower conductive layer 14c and the upper conductive layer 16c. Note that the upper conductive layer 16c in FIG. 3 is electrically connected to the power supply line 18g through a contact hole formed in the second interlayer insulating film 17.

The planarization film 20 has a flat surface in the display region D. The planarization film 20 is made of, for example, an organic resin material such as polyimide resin.

As illustrated in FIG. 3, the organic EL element layer 40 includes: a plurality of first electrodes 31; a plurality of the third electrodes 32a; a first edge cover 33 provided in common; a plurality of fourth electrodes 34; a second edge cover 35 provided in common; a plurality of the organic EL layers 36; and a second electrode 37 provided in common, all of which are sequentially stacked on top of another in association with the plurality of subpixels P. Here, in each of the subpixels P, a first electrode 31, a third electrode 32a, a fourth electrode 34, an organic EL layer 36, and the second electrode 37 constitute an organic EL element 39 as illustrated in FIG. 3. In the organic EL element layer 40, a plurality of the organic EL elements 39 are arranged in a matrix in association with the plurality of subpixels P.

The first electrode 31 illustrated in FIG. 3 is electrically connected to the drain electrode 18d of the second TFT 9b for each subpixel P, through a contact hole formed in the protective insulating film 19 and the planarization film 20. Here, the first electrode 31 is, for example, a transparent conductive film formed of such a substance as indium tin oxide (ITO). The first electrode 31 is transparent to light. Furthermore, as will be described later, the first electrode 31 is made of crystal grains contained in a transparent conductive film and having a predetermined crystallographic orientation.

The third electrode 32a illustrated in FIG. 3 is provided on the first electrode 31 so that a peripheral end portion of the third electrode 32a overlaps with a peripheral end portion of the first electrode 31. Moreover, similar to the first electrode 31, the third electrode 32a is, for example, a transparent conductive film formed of such a substance as ITO. The third electrode 32a is transparent to light. In addition, as will be described later, the third electrode 32a is made of crystal gains contained in a transparent conductive film and having a predetermined crystallographic orientation. A crystallographic orientation of the crystal grains contained in the third electrode 32a is equivalent to a crystallographic orientation of the crystal grains contained in each of the first electrodes 31 and continuing in a thickness direction of the resin substrate 10. Furthermore, as will be described later, the third electrode 32a has the peripheral end portion covered with the first edge cover 33. As illustrated in FIG. 3, the third electrode 32a exposed from the first edge cover 33 is provided with a plurality of opening portions M dotted at random and penetrating through the third electrode 32a so that the first electrode 31 is exposed through the opening portions M. Here, each of the opening portions M is sized to have a diameter of, for example, approximately 100 nm and a depth of, for example, approximately 50 nm. Moreover, the opening portions M of the third electrode 32a are provided by removing amorphous portions and microcrystalline portions from the transparent conductive film that serves as the third electrode 32a. Note that this embodiment exemplifies the opening portions M provided to penetrate through the third electrode 32a. Alternatively, the opening portions M may be provided to open toward the fourth electrode 34 without penetrating through the third electrode 32a.

The first edge cover 33 is provided in a grid pattern over the entire display region D. As illustrated in FIG. 3, the first edge cover 33 is provided to cover the peripheral end portion of the third electrode 32a. Here, the first edge cover 33 is made of, for example, an organic resin material such as polyimide resin or acrylic resin, or a polysiloxane-based spin-on-glass (SOG) material.

The fourth electrode 34 is capable of injecting holes into the organic EL layer 36. As illustrated in FIG. 3, the fourth electrode 34 is provided to cover the third electrode 32a exposed from the first edge cover 33. Moreover, the fourth electrode 34 is preferably formed of a material having a large work function to improve efficiency in injecting the holes into the organic EL layer 36. Here, the fourth electrode 34 is formed of, for example, a multilayer film including: a transparent conductive film made of such a substance as ITO; a metal film made of such a metal as silver (Ag); and a transparent conductive film made of such a substance as ITO, all of which are sequentially stacked on top of another. The fourth electrode 34 is reflective to light. Furthermore, as illustrated in FIG. 3, the fourth electrode 34 has a surface provided with a plurality of recess portions C in association with the plurality of opening portions M of the third electrode 32a. Hence, the surface of the fourth electrode 34 has a nano-scale asperity structure because of the opening portions M of the third electrode 32a.

The second edge cover 35 is provided in a grid pattern over the entire display region D. As illustrated in FIG. 3, the second edge cover 35 is provided to cover the peripheral end portion of the fourth electrode 34. Here, the second edge cover 35 is made of an inorganic monolayer insulating film of such a substance as, for example, silicon nitride, silicon oxide, or silicon oxynitride. Alternatively, the second edge cover 35 is made of an inorganic multilayer insulating film including these substances.

The organic EL layer 36 is provided as a light-emitting functional layer. As illustrated in FIG. 5, the organic EL layer 36 includes: a hole injection layer 1; a hole transport layer 2; a light-emitting layer 3; an electron transport layer 4; and an electron injection layer 5, all of which are sequentially stacked on top of another above the fourth electrode 34. Here, as will be described later, each of the hole injection layer 1, the hole transport layer 2, the light-emitting layer 3, the electron transport layer 4, and the electron injection layer 5 is formed of an aqueous solution in which a material of the corresponding layer is dissolved. The solution is applied and dried to form the layer.

The hole injection layer 1 is also referred to as an anode buffer layer. The hole injection layer 1 has a function of approximating energy levels between the fourth electrode 34 and the organic EL layer 36 to improve efficiency in injecting the holes from the fourth electrode 34 into the organic EL layer 36. Here, examples of a material forming the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has a function of improving efficiency in transporting the holes from the fourth electrode 34 to the organic EL layer 36. Here, examples of a material forming the hole transport layer 2 include a porphyrin derivative, an aromatic tertiary amine compound, a styrylamine derivative, polyvinyl carbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, zinc selenide, and zinc selenide.

The light-emitting layer 3 is a region where the holes and the electrons are respectively injected from the fourth electrode 34 and the second electrode 37, and recombine together, when a voltage is applied with the fourth electrode 34 and the second electrode 37. Here, the light-emitting layer 3 is formed of a material having high light emission efficiency. Examples of the material forming the light-emitting layer 3 include a metal oxinoid compound [8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rhodamine derivative, an aquizine derivative, phenoxazone, a quinacridone derivative, rubrene, poly-p-phenylenevinylene, and polysilane.

The electron transport layer 4 has a function of efficiently moving the electrons to the light-emitting layer 3. Here, examples of a material forming the electron transport layer 4 include, as organic compounds, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has a function of approximating energy levels between the second electrode 37 and the organic EL layer 36 to improve efficiency in injecting the electrons from the second electrode 37 into the organic EL layer 36. Such a function can decrease a drive voltage of the organic EL element 39. Note that the electron injection layer 5 is also referred to as a cathode buffer layer. Here, examples of a material forming the electron injection layer 5 include: inorganic alkali compounds such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 37 is provided to cover each organic EL layer 36 and the second edge cover 35. Moreover, the second electrode 37 has a function of injecting the electrons into the organic EL layer 36. Furthermore, the second electrode 37 is preferably formed of a material having a small work function to improve efficiency in injecting the electrons into the organic EL layer 36. Here, the second electrode 37 is, for example, a transparent conductive film formed of such a substance as ITO. The second electrode 37 is transparent to light.

As illustrated in FIG. 3, the sealing film 45 is provided to cover the second electrode 37, and includes: a first inorganic sealing film 41; an organic sealing film 42; and a second inorganic sealing film 43, all of which are sequentially stacked on top of another above the second electrode 37. The sealing film 45 has a function of protecting the organic EL layer 36 in the organic EL element 39 from moisture and oxygen. Here, each of the first inorganic sealing film 41 and the second inorganic sealing film 43 is formed of such an inorganic insulating film as, for example, a silicon nitride film, a silicon oxide film, or a silicon oxynitride film. Moreover, the organic sealing film 42 is formed of such an organic resin material as, for example, acrylic resin, epoxy resin, silicone resin, polyurea resin, parylene resin, polyimide resin, or polyamide resin.

The above organic EL display device 50 displays an image as follows: In each of the subpixels P, a gate signal is input to the first TFT 9a through the gate line 14g to turn ON the first TFT 9a. Through the source line 18f, a data signal is written to the gate electrode 14b of the second TFT 9b and the capacitor 9c. A current based on a gate voltage of the second TFT 9b is supplied from the power supply line 18g to the organic EL layer 36, and the light-emitting layer 3 of the organic EL layer 36 emits light to display an image. Note that, in the organic EL display device 50, even if the first TFT 9a turns OFF, the gate voltage of the second TFT 9b is held in the capacitor 9c. Hence, the light-emitting layer 3 keeps emitting light until a gate signal in the next frame is input.

Described next will be a method for producing the organic EL display device 50 of this embodiment. Here, the method for producing the organic EL display device 50 of this embodiment includes: a TFT-layer forming step; an organic-EL-element-layer forming step; and a sealing-film forming step.

### TFT-Layer Forming Step

First, a silicon nitride film (approximately 50 nm in thickness) and a silicon oxide film (approximately 250 nm in thickness) are sequentially deposited by, for example, plasma chemical vapor deposition (CVD) on the resin substrate 10 formed on a glass substrate. Hence, the base coat film 11 is formed.

Then, on a substrate surface provided with the base coat film 11, an amorphous silicon film (approximately 50 nm in thickness) is deposited by, for example, the plasma CVD. The amorphous silicon film is crystallized by such a technique as laser annealing to form a semiconductor film made of polysilicon. After that, the semiconductor film is patterned to form such layers as the semiconductor layers 12a and 12b.

After that, on the substrate surface provided with the semiconductor layer 12a, a silicon oxide film (approximately 100 nm in thickness) is deposited by, for example, the plasma CVD to form the gate insulating film 13.

Furthermore, on the substrate surface provided with the gate insulating film 13, a first metal film such as a molybdenum film (approximately 200 nm in thickness) is formed by, for example, sputtering. After that, the first metal film is patterned to form, for example, the gate electrodes 14a and 14b.

Then, using the gate electrodes 14a and 14b as masks, the semiconductor layers 12a and 12b are doped with impurity ions so that portions of the semiconductor layers 12a and 12b become conductive to form the source region, the drain region, and the channel region in each of the semiconductor layers 12a and 12b.

After that, on the substrate surface of the conductive portions in the semiconductor layers 12a and 12b, a silicon nitride film (approximately 150 nm in thickness) and a silicon oxide film (approximately 100 nm in thickness) are sequentially deposited by, for example, the plasma CVD. Hence, the first interlayer insulating film 15 is formed.

Furthermore, on the substrate surface provided with the first interlayer insulating film 15, a second metal film such as a molybdenum film (approximately 200 nm in thickness) is formed by, for example, sputtering. After that, the second metal film is patterned to form, for example, the upper conductive layer 16c.

After that, on the substrate surface provided with the upper conductive layer 16c, a silicon oxide film (approximately 300 nm in thickness) and a silicon nitride film (approximately 150 nm in thickness) are sequentially deposited by, for example, the plasma CVD. Hence, the second interlayer insulating film 17 is formed.

Subsequently, on the substrate surface provided with the second interlayer insulating film 17, the first gate insulating film 13, the first interlayer insulating film 15, and the second interlayer insulating film 17 are patterned as appropriate. Hence, contact holes are formed.

After that, on the substrate surface having the contact holes, a titanium film (approximately 50 nm in thickness), an aluminum film (approximately 400 nm in thickness), and a titanium film (approximately 100 nm in thickness) are sequentially deposited by, for example, sputtering to form a third metal film. After that, the third metal film is patterned to form such electrodes as the source electrodes 18a and 18c, and the drain electrodes 18b and 18d.

Furthermore, on the substrate surface provided with such an electrode as the source electrode 18a, a silicon oxide film (approximately 250 nm in thickness) is deposited by, for example, the plasma CVD to form the protective insulating film 19.

Subsequently, the substrate surface provided with the protective insulating film 19 is coated with an acrylic-based photosensitive resin film (approximately 2 μm in thickness) by, for example, spin coating or slit coating. After that, the coating film is pre-baked, exposed to light, developed, and post-baked to form the planarization film 20 having a contact hole.

Finally, the protective insulating film 19 exposed from the contact hole of the planarization film 20 is removed, so that the contact hole reaches the drain electrode 18d of the second TFT 9b.

As described above, the TFT layer 30 is successfully formed.

### Organic-EL-Element-Layer Forming Step

First, on the substrate surface provided with the TFT layer 30 formed at the TFT-layer forming step, a transparent conductive film such as an ITO film (approximately 50 nm in thickness) is deposited by, for example, sputtering. After that, the transparent conductive film is patterned to form the first electrode 31. Specifically, when the first electrode 31 is formed, for example, an amorphous ITO film is deposited by sputtering, using a sputtering gas containing an argon gas, an oxygen gas, and water vapor. After that, the amorphous ITO film is patterned, and then crystallized by annealing, to form the first electrode 31 made of a crystalline ITO film. (See FIG. 6(a)). Note that, in FIG. 6(a), three kinds of hatching patterns are used to schematically show that the first electrode 31 is formed of three kinds of crystal grains each having a different crystallographic orientation.

Next, on the substrate surface provided with the first electrode 31, a transparent conductive film such as an ITO film (approximately 50 nm in thickness) is deposited by, for example, sputtering. After that, the transparent conductive film is patterned to form the third electrode 32a. Specifically, when the third electrode 32a is formed, an ITO film 32 is deposited to include a crystalline portion, an amorphous portion, and a microcrystalline portion by, for example, sputtering using a sputtering gas containing an argon gas, an oxygen gas, and water vapor. After that, the amorphous portion and the microcrystalline portion (i.e., dotted patterns in FIG. 6(b)) of the ITO film 32 are removed by wet-etching using such a substance as oxalic acid. Hence, the third electrode 32a is formed to have the opening portions M. (See FIGS. 6(b) and 6(c)). Here, if a flow rate of the water vapor in the sputtering gas is low, as illustrated in FIG. 6(d), the ITO film 32 is formed of crystal grains (the hatching patterns in the drawings) having a crystallographic orientation equivalent to a crystallographic orientation of crystal grains of the first electrode 31, so that the crystal grains of the ITO film 32 are aligned with (the crystal grains of) the first electrode 31; that is, the crystallographic orientation of the crystal grains of the ITO film 32 continues in a thickness direction of the resin substrate 10. Furthermore, if the flow rate of the water vapor in the sputtering gas is high, as illustrated in FIG. 6(e), the ITO film 32 is formed to include only the amorphous portion and the microcrystalline portion (i.e., the dotted pattern in the drawing). Then, if the flow rate of the water vapor in the sputtering gas is an appropriate rate, as illustrated in FIG. 6(b), the ITO film 32 is formed to have the amorphous portion and the microcrystalline portion (i.e., the dotted patterns in the drawing) randomly arranged between the crystal grains (i.e., the hatching patterns in the drawing) having the crystallographic orientation equivalent to the crystallographic orientation of the crystal grains of the first electrode 31.

Furthermore, the substrate surface of the third electrode 32a is coated with an acrylic-based photosensitive resin film (approximately 2 μm in thickness) by, for example, spin coating or slit coating. After that, the coating film is pre-baked, exposed to light, developed, and post-baked to form the first edge cover 33.

After that, on the substrate surface provided with the first edge cover 33, a transparent conductive film such as an ITO film (approximately 40 nm in thickness), a metal film such as a Ag film (approximately 20 nm in thickness), and a transparent conductive film such as an ITO film (approximately 40 nm in thickness) are sequentially deposited by, for example, sputtering. After that, the multilayer film including these films are patterned to form the fourth electrode 34 having the recess portions C.

Furthermore, on the substrate surface provided with the fourth electrode 34, an inorganic insulating film such as a silicon nitride film (approximately 250 nm in thickness) is deposited by, for example, the plasma CVD. After that, the inorganic insulating film is patterned to form the second edge cover 35.

Subsequently, on the substrate surface provided with the second edge cover 35, aqueous solutions each containing a predetermined material of the corresponding layer dissolved therein are repeatedly applied by, for example, inkjet printing, and dried. The aqueous solutions sequentially form the hole injection layer 1, the hole transport layer 2, the light-emitting layer 3, the electron transport layer 4, and the electron injection layer 5, each of which has a thickness of several tens of namometers to several hundreds of namometers. The layers form the organic EL layer 36.

Finally, on the substrate surface provided with the organic EL layer 36, a transparent conductive film such as, for example, an ITO film (approximately 100 nm in thickness) is deposited by sputtering using a mask. Hence, the second electrode 37 is formed.

As described above, the organic-EL-element layer 40 is successfully formed.

### Sealing-Film Forming Step

First, on the substrate surface provided with the organic-EL-element layer 40 formed at the organic-EL-element-layer forming step, an inorganic insulating film such as, for example, a silicon nitride film, a silicon oxide film, or a silicon oxynitride film is deposited by the plasma CVD, using a mask. Hence, the first inorganic sealing film 41 is formed.

Then, on the substrate surface provided with the first inorganic sealing film 41, an organic resin material such as acrylic resin is deposited by, for example, inkjet printing. Hence, the organic sealing film 42 is formed.

Furthermore, on the substrate provided with the organic sealing film 42, an inorganic insulating film such as, for example, a silicon nitride film, a silicon oxide film, or a silicon oxynitride film is deposited by the plasma CVD, using a mask, to form the second inorganic sealing film 43. Hence, the sealing film 45 is formed.

Finally, a protective sheet (not shown) is attached to the substrate surface provided with the sealing film 45. After that, a laser beam is emitted from toward the glass substrate of the resin substrate 10, and the glass substrate is removed from a lower surface of the resin substrate 10. Moreover, a protective sheet (not shown) is attached to the lower surface of the resin substrate 10 from which the glass substrate is removed.

As can be seen, the organic EL display device 50 of this embodiment is successfully produced.

As can be seen, in the organic EL display device 50 of this embodiment, each of the third electrodes 32a exposed from the first edge cover 33 has the plurality of opening portions M dotted and penetrating through the third electrode 32a so that each of the first electrodes 31 is exposed through the opening portions M. The surface of each of the fourth electrodes 34 is provided with the plurality of recess portions C in association with the plurality of opening portions M. Here, solute components contained in the organic EL layer 36 and formed on the surface of each of the fourth electrodes 34 by coating and drying are likely to flow around typically by the coffee ring effect. Each of the solute components is less likely to flow around thanks to an increase in the surface area of the solute component because of the plurality of recess portions C formed on the surface of each fourth electrode 34. Such a feature reduces differences in film thickness of the organic EL layer 36 formed by coating and drying on the surface of each fourth electrode 34, thereby successfully reducing variations in the thickness of the organic EL layer 36 in the subpixel P. Furthermore, the feature can reduce variations in the thickness of the organic EL layer 36 in the subpixel P, thereby successfully reducing unevenness in emission of light from the organic EL element 39 of each of the subpixels P and curbing a decrease in light emission efficiency.

Furthermore, according to the organic EL display device 50 of this embodiment, the opening portions M of each of the third electrodes 32a are formed not by photolithography but by removal of the amorphous portion and the microcrystalline portion from the transparent conductive film 32 at the crystal level. Such a feature makes it possible to form a nano-scale asperity structure on the surface of each of the fourth electrodes 34, using the plurality of recess portions C. The asperities can reliably reduce variations of the organic EL layer 36 formed of the hole injection layer 1, the hole transport layer 2, the light-emitting layer 3, the electron transport layer 4, and the electron injection layer 5, each of which has a thickness of several tens of namometers to several hundreds of namometers and all of which are stacked on top of another.

Furthermore, according to the organic EL display device 50 of this embodiment, the asperity structure formed, using the plurality of recess portions C, on the surface of each of the fourth electrodes 34 is on the nano-scale and has small asperities. Hence, even if each of the hole injection layer 1, the hole transport layer 2, the light-emitting layer 3, the electron transport layer 4, and the electron injection layer 5 is thin, the nano-scale asperity structure can reduce a short circuit between the first electrode 31 and the second electrode 37 in each of the subpixels P.

### OTHER EMBODIMENTS

In the above embodiment, the exemplified organic EL layer has a multilayer structure including five layers such as a hole injection layer, a hole transport layer, a light-emitting layer, an electron transport layer, and an electron injection layer. Alternatively, the organic EL layer may have a multilayer structure including three layers such as, for example, a hole-injection-and-hole-transport layer, a light-emitting layer, and an electron-transport-and-electron-injection layer.

Furthermore, in the above embodiment, the exemplified organic EL display device in which an electrode of a TFT connected to a first electrode is a drain electrode. The present invention can also be applied to an organic EL display device in which an electrode of a TFT connected to a first electrode is referred to as a source electrode.

In addition, in the above embodiment, the organic EL display device is exemplified as a display device. The present invention can be applied to a display device including a plurality of light-emitting elements driven by currents. For example, the present invention can be applied to a display device including quantum-dot light-emitting diodes (QLEDs); that is, light-emitting elements including layers containing quantum dots.

### INDUSTRIAL APPLICABILITY

As described above, the present invention is useful for a flexible display device.

Reference Signs List

| C | Recess Portion |
|---|---|
| D | Display Region |
| M | Opening Portion |
| P | Subpixel |
| 10 | Resin Substrate (Base Substrate) |
| 30 | TFT Layer (Thin-Film Transistor Layer) |
| 31 | First Electrode |
| 32a | Third Electrode |
| 33 | First Edge Cover |
| 34 | Fourth Electrode |
| 35 | Second Edge Cover |
| 36 | Organic EL Layer (Organic Electroluminescent |
| | Layer, Light-Emitting Functional Layer) |
| 37 | Second Electrode |
| 40 | Organic-EL-Element Layer (Light-Emitting-Element Layer) |
| 45 | Sealing Film |
| 50 | Organic EL Display Device |

1. A display device, comprising:
a base substrate;
a thin-film transistor layer provided on the base substrate; and
a light-emitting-element layer provided on the thin-film transistor layer, and including a plurality of first electrodes, a first edge cover provided in common, a plurality of light-emitting functional layers, and a second electrode provided in common, all of which are sequentially stacked on top of another in association with a plurality of subpixels that constitute a display region,
wherein, between the plurality of first electrodes and the first edge cover, a plurality of third electrodes is provided in association with the plurality of subpixels,
each of the third electrodes exposed from the first edge cover is provided with a plurality of opening portions penetrating through the third electrode,
between the first edge cover and the plurality of light-emitting functional layers, a plurality of fourth electrodes is provided in association with the plurality of subpixels to cover the plurality of third electrodes exposed from the first edge cover, and
each of the fourth electrodes has a surface provided with a plurality of recess portions in association with the plurality of opening portions.

2. The display device according to claim 1,
wherein each of the first electrodes, the second electrode, and each of the third electrodes is transparent to light, and
each of the fourth electrodes is reflective to light.

3. The display device according to claim 1,
wherein each of the first electrodes and the third electrodes is made of crystal grains contained in a transparent conductive film and having a predetermined crystallographic orientation, and
a crystallographic orientation of the crystal grains contained in each of the third electrodes is equivalent to a crystallographic orientation of the crystal grains contained in each of the first electrodes and continuing to the crystal grains of each of the third electrodes in a thickness direction of the base substrate.

4. The display device according to claim 3,
wherein each of the opening portions is provided by removing an amorphous portion and a microcrystalline portion from the transparent conductive film.

5. The display device according to claim 3,
wherein the transparent conductive film is made of indium oxide tin.

6. The display device according to claim 1,
wherein the surface of each of the fourth electrodes has a nano-scale asperity structure.

7. The display device according to claim 1,
wherein, between the plurality of fourth electrodes and the plurality of light-emitting functional layers, a second edge cover is provided in common in association with the plurality of subpixels, and
the second edge cover is provided to cover a peripheral end portion of each of the fourth electrodes.

8. The display device according to claim 7,
wherein the first edge cover is made of an organic resin material, and
the second edge cover is made of an inorganic insulating film.

9. The display device according to claim 1, further comprising
a sealing film provided on the light-emitting-element layer.

10. The display device according to claim 1,
wherein each of the light-emitting functional layers is an organic electroluminescence layer.
